(19) United States
(12) Patent Application Publication
(10) Pub. No.: US 2005/0136687 A1
(43) Pub. Date: Jun. 23, 2005

(54) Porous silica dielectric having improved etch selectivity towards inorganic anti-reflective coating materials for integrated circuit applications, and methods of manufacture

(75) Inventors: Victor Y. Lu, Santa Cruz, CA (US); Bo Li, San Jose, CA (US); Deling Zhou, Sunnyvale, CA (US); Roger Y. Leung, San Jose, CA (US); Paul G. Apen, San Francisco, CA (US)

Correspondence Address: Richard S. Roberts;Roberts & Mercanti, LLP, P.O. Box 484, Princeton, NJ, 08542-0484, US

(73) Assignee: Honeywell International Inc

(21) Appl. No.: 10/741,272

(22) Filed: Dec. 19, 2003

(51) Int. Cl. H01L 21/76; H01L 21/31; H01L 21/469

(52) U.S. Cl. 438/781; 438/446

(57) ABSTRACT

A composition comprising a nanoporous silica dielectric film having a void volume of about 30% or less based on the total volume of the nanoporous silica dielectric film, and having a dielectric constant of about 2.2 or less. A method of producing a nanoporous silica dielectric film having a void volume of about 30% or less based on the total volume of the nanoporous silica dielectric film, and having a dielectric constant of about 2.2 or less. A silicon containing pre-polymer is provided, which is capable of forming a film having a dielectric constant of about 2.8 or less. It is then combined with a porogen, and a metal-ion-free catalyst selected from the group consisting of onium compounds and nucleophiles, to thereby form a composition. A layer of the composition is coated on to a substrate, crosslinked to form a gelled film, and heated to remove substantially all of the porogen and to thereby produce a nanoporous silica dielectric film of the invention.

### BACKGROUND OF THE INVENTION

1. Field of the Invention

The present invention relates to the production of nanoporous silica dielectric films and to semiconductor devices and integrated circuits comprising these films. The nanoporous films are prepared by a process which includes combining a silicon containing pre-polymer with a porogen and a catalyst. The resulting composition is used to form a dielectric layer having low porosity, low k, and enhanced etch selectivity towards inorganic bottom anti-reflective coating (BARC) materials.

2. Description of the Related Art

As feature sizes in integrated circuits are reduced to below 0.15 μm and below, problems with interconnect RC delay, power consumption and signal cross-talk have become increasingly difficult to resolve. It is believed that the integration of low dielectric constant materials for interlevel dielectric (ILD) and intermetal dielectric (IMD) applications will help to solve these problems. While there have been previous efforts to apply low dielectric constant materials to integrated circuits, there remains a longstanding need in the art for further improvements in processing methods and in the optimization of both the dielectric and mechanical properties of such materials used in the manufacture of integrated circuits.

One type of material with a low k is nanoporous silica formed from spin-on sol-gel techniques. Nanoporous silica formulated using a tetraacetoxysilane (TAS)/methyltriacetoxysilane(MTAS)-derived silicon polymer as the base matrix and polyethylene glycol monomethyl ether as the porogen have demonstrated high mechanical strength as indicated in its modulus and stud pull data. However, such do not exhibit sufficient etch selectivity towards existing inorganic BARC materials.

### SUMMARY OF THE INVENTION

In order to achieve etch selectivity towards existing inorganic BARC, porous silica with low porosity, smaller pore size, higher carbon content and resistance towards strippers for the BARC is desired. In addition, low metal content tetraacetoxysilane (TAS) is an expensive raw material because of the tedious synthesis and purification steps required. One way of improving TAS/MTAS compositions is to drive down the cost of its raw materials. In addition, the existing technology for the preparation of TAS/MTAS nanoporous silica requires heating and cooling steps that could drive up the cost of ownership as well. Therefore, there is a need to develop a low metal content nanoporous silica film that can consistently give dielectric constant of less than 2.5 and superior etch selectivity towards other inorganic BARC materials.

The present invention uses a commercially available, inexpensive methyltriacetoxysilane (MTAS), poly(ethylene glycol)dimethyl ether (DMEPEO) and tetramethylammonium acetate (TMAA) for forming a porous silica. The preparation requires an intimate admixture of MTAS with water prior to the addition of DMEPEO and TMAA. The process does not require a special reactor or controlled heating/cooling steps, thus lowering the cost of production. The processed films from the solution exhibit high water contact angle, lower porosity, and extremely high etch selectivity towards BARC materials that currently used for IC applications.

The present invention relates to a method of producing a nanoporous silica dielectric film. A silicon containing pre-polymer is provided, which has a dielectric constant of about 2.8 or less, and which is optionally mixed with water. Next, the pre-polymer is combined with a porogen, and a metal-ion-free catalyst selected from the group consisting of onium compounds and nucleophiles, to thereby form a composition.

The term “pore” as used herein includes voids and cells in a material, and any other term meaning a space occupied by gas in the material. Appropriate gases include relatively pure gases and mixtures thereof. Air, which is predominantly a mixture of N₂ and O₂, is commonly distributed in the pores, but pure gases such as nitrogen, helium, argon, CO₂, or CO are also contemplated. Pores are typically spherical but may alternatively or additionally include tubular, lamellar, or discoidal voids, voids having other shapes, or a combination of the preceding shapes, and may be open or closed.

The term “porogen” as used herein means a decomposable material that is radiation, thermally, chemically, or moisture decomposable, degradable, depolymerizable, or otherwise capable of breaking down, and includes solid, liquid, or gaseous material. The decomposed porogen is removable from or can volatilize or diffuse through a partially or fully cross-linked matrix to create pores in a subsequently fully cured matrix and thus, lower the matrix's dielectric constant, and includes sacrificial polymers. Supercritical materials such as CO₂ may be used to remove the porogen and/or decomposed porogen fragments. For a thermally decomposable porogen, the porogen should comprise a material having a decomposition temperature less than the glass transition temperature (Tg) of a dielectric material combined with it and greater than the crosslinking temperature of the dielectric material combined with it. Thus, the dielectric material and porogen are different materials. Porogens may have a degradation or decomposition temperature of about 350° C. or lower.

A layer of the composition is coated onto a substrate, followed by crosslinking the composition to produce a gelled film. The gelled film is then heated at a temperature and for a duration effective to remove substantially all of the porogen to thereby produce a nanoporous silica dielectric film having a void volume of about 30% or less based on the total volume of the nanoporous silica dielectric film, and having a dielectric constant of about 2.2 or less.

The invention provides a method of producing a nanoporous silica dielectric film comprising:
(a) providing a silicon containing pre-polymer capable of forming a film with a dielectric constant of about 2.8 or less, which pre-polymer is optionally mixed with water; thereafter
(b) combining the result of (a) with a porogen, and a metal-ion-free catalyst selected from the group consisting of onium compounds and nucleophiles, to thereby form a composition; then
(c) coating a layer of the composition onto substrate; then
(d) crosslinking the composition to produce a gelled film, and then
(e) heating the gelled film at a temperature and for a duration effective to remove substantially all of said porogen to thereby produce a nanoporous silica dielectric film having a void volume of about 30% or less based on the total volume of the nanoporous silica dielectric film, and having a dielectric constant of about 2.2 or less.

The invention further provides a nanoporous dielectric film produced by a process comprising the steps of:
(a) providing a silicon containing pre-polymer capable of forming a film with a dielectric constant of about 2.8 or less, which pre-polymer is optionally mixed with water; thereafter
(b) combining the result of (a) with a porogen, and a metal-ion-free catalyst selected from the group consisting of onium compounds and nucleophiles, to thereby form a composition; then
(c) coating a layer of the composition onto substrate; then
(d) crosslinking the composition to produce a gelled film, and then
(e) heating the gelled film at a temperature and for a duration effective to remove substantially all of said porogen to thereby produce a nanoporous silica dielectric film having a void volume of about 30% or less based on the total volume of the nanoporous silica dielectric film, and having a dielectric constant of about 2.2 or less.

The invention still further provides a nanoporous dielectric film containing device produced by a process comprising the steps of:
(a) providing a silicon containing pre-polymer capable of forming a film with a dielectric constant of about 2.8 or less, which pre-polymer is optionally mixed with water; thereafter
(b) combining the result of (a) with a porogen, and a metal-ion-free catalyst selected from the group consisting of onium compounds and nucleophiles, to thereby form a composition; then
(c) coating a layer of the composition onto substrate; then
(d) crosslinking the composition to produce a gelled film, and then
(e) heating the gelled film at a temperature and for a duration effective to remove substantially all of said porogen to thereby produce a nanoporous silica dielectric film having a void volume of about 30% or less based on the total volume of the nanoporous silica dielectric film, and having a dielectric constant of about 2.2 or less;
(f) depositing a layer of a photoresist onto the nanoporous silica dielectric film, and imagewise removing a portion of the photoresist over some areas of the film to form a pattern;
(g) conducting a dry etch treatment of the nanoporous silica dielectric film such that areas of the film under the removed portion of the photoresist form at least one via or trench through the nanoporous silica dielectric film, said at least one via and/or trench defining sidewalls and a floor;
(h) conducting a dry ash treatment such that the remainder of the photoresist is removed; and
(i) depositing an anti-reflective coating material into the at least one via and/or trench.

The invention provides a nanoporous silica dielectric film A nanoporous silica dielectric film having a void volume of about 30% or less based on the total volume of the nanoporous silica dielectric film, and having a dielectric constant of about 2.2 or less.

The invention provides a nanoporous silica dielectric film having a void volume of about 30% or less based on the total volume of the nanoporous silica dielectric film, and having a dielectric constant of about 2.2 or less, and having an average pore diameter in the range of from about 1 nm to about 30 nm.

The invention provides a nanoporous silica dielectric film, having a void volume of about 30% or less based on the total volume of the nanoporous silica dielectric film, and having a dielectric constant of about 2.2 or less, on the substrate.

The invention provides a nanoporous silica dielectric film, having a void volume of about 30% or less based on the total volume of the nanoporous silica dielectric film, and having a dielectric constant of about 2.2 or less, on the substrate having metallic lines on the surface of substrate.

The invention provides a nanoporous silica dielectric film, having a void volume of about 30% or less based on the total volume of the nanoporous silica dielectric film, and having a dielectric constant of about 2.2 or less, on the substrate comprising a semiconductor material.

The invention provides a nanoporous silica dielectric film, having a void volume of about 30% or less based on the total volume of the nanoporous silica dielectric film, and having a dielectric constant of about 2.2 or less, on the substrate comprising a semiconductor material such as silicon, gallium arsenide, silicon nitride, silicon oxide, silicon oxycarbide, silicon dioxide, silicon carbide, silicon oxynitride, titanium nitride, tantalum nitride, tungsten nitride, aluminum, copper, tantalum, organosiloxanes, organo silicon glass, fluorinated silicon glass or combinations thereof.

The invention provides a nanoporous silica dielectric film, having a void volume of about 30% or less based on the total volume of the nanoporous silica dielectric film, having a dielectric constant of about 2.2 or less, and patterned to have formed at least one via and/or trench therein.

The invention provides a microelectronic device comprising a nanoporous silica dielectric film, having a void volume of about 30% or less based on the total volume of the nanoporous silica dielectric film, and having a dielectric constant of about 2.2 or less, and having an anti-reflective coating material deposited into the at least one via and/or trench.

### DETAILED DESCRIPTION OF THE PREFERRED EMBODIMENT

The invention relates to the formation of a nanoporous silica dielectric film. The nanoporous silica dielectric film resulting from the method of the present invention has a void volume of about 30% or less based on the total volume of the nanoporous silica dielectric film, and has a dielectric constant of about 2.2 or less. The invention further relates to a nanoporous silica dielectric film having a void volume of about 30% or less based on the total volume of the nanoporous silica dielectric film, and having a dielectric constant of about 2.2 or less.

The nanoporous silica dielectric film of the invention is formed by combining a silicon-containing pre-polymer with at least one porogen, and at least one metal-ion-free catalyst, to thereby form a composition.

First, at least one silicon-containing pre-polymer is provided which is capable of forming a pre-polymer film with a dielectric constant of about 2.8 or less.

In another embodiment, the pre-polymer is capable of forming a pre-polymer film with a dielectric constant of about 2.40 to about 2.65. The silicon containing prepolymer should be readily condensed. It should have at least two reactive groups that can be hydrolyzed. Such reactive groups include, alkoxy (RO), acetoxy (AcO), etc. Without being bound by any theory or hypothesis as to how the methods and compositions of the invention are achieved, it is believed that water hydrolyzes the reactive groups on the silicon monomers to form Si—OH groups (silanols). The latter will undergo condensation reactions with other silanols or with other reactive groups, as illustrated by the following formulas:
Si—OH+HO—Si→Si—O—Si+H₂O
Si—OH+RO—Si→Si—O—Si+ROH
Si—OH+AcO—Si→Si—O—Si+AcOH
Si—OAc+AcO—Si→Si—O—Si+Ac₂O
R=alkyl or aryl
Ac=acyl(CH₃CO)

These condensation reactions lead to formation of silicon containing polymers. In one embodiment of the invention, the prepolymer includes a compound, or any combination of compounds, denoted by Formula I:
Rx-Si-Ly (Formula I)
wherein x is an integer ranging from 0 to about 2 and y is 4-x, an integer ranging from about 2 to about 4,
R is independently alkyl, aryl, hydrogen, alkylene, arylene and/or combinations of these,
L is independently selected and is an electronegative group, e.g., alkoxy, carboxyl, amino, amido, halide, isocyanato and/or combinations of these.

Particularly useful prepolymers are those provided by Formula I when x ranges from about 0 to about 2, y ranges from about 2 to about 4, R is alkyl or aryl or H, and L is an electronegative group.

Examples of suitable compounds according to Formula I include, but are not limited to:
Si(OCH₂CF₃)₄ tetrakis(2,2,2-trifluoroethoxy)silane,
Si(OCOCF₃)₄ tetrakis(trifluoroacetoxy)silane*,
Si(OCN)₄ tetraisocyanatosilane,
CH₃Si(OCH₂CF₃)₃ tris(2,2,2-trifluoroethoxy)methylsilane,
CH₃Si(OCOCF₃)₃ tris(trifluoroacetoxy)methylsilane*,
CH₃Si(OCN)₃ methyltriisocyanatosilane,
   and or combinations of any of the above.
   [* These generate acid catalysts upon exposure to water]

In another embodiment of the invention, a polymer is synthesized from compounds denoted by Formula I by way of hydrolysis and condensation reactions, wherein the number average molecular weight ranges from about 150 to about 300,000 amu, or more typically from about 150 to about 10,000 amu.

In a further embodiment of the invention, silicon-containing prepolymers useful according to the invention include organosilanes, including, for example, alkoxysilanes according to Formula II:

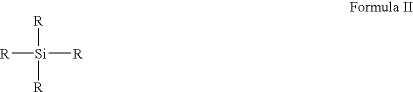

Optionally, Formula II is an alkoxysilane wherein at least 2 of the R groups are independently C₁ to C₄ alkoxy groups, and the balance, if any, are independently selected from the group consisting of hydrogen, alkyl, phenyl, halogen, substituted phenyl. For purposes of this invention, the term alkoxy includes any other organic groups which can be readily cleaved from silicon at temperatures near room temperature by hydrolysis. R groups can be ethylene glycoxy or propylene glycoxy or the like. In one embodiment, all four R groups are methoxy, ethoxy, propoxy or butoxy. In another embodiment, alkoxysilanes nonexclusively include tetraethoxysilane (TEOS) and tetramethoxysilane.

In a further option, for instance, the prepolymer can also be an alkylalkoxysilane as described by Formula II, but instead, at least 2 of the R groups are independently C₁ to C₄ alkylalkoxy groups wherein the alkyl moiety is C₁ to C₄ alkyl and the alkoxy moiety is C₁ to C₆ alkoxy, or ether-alkoxy groups; and the balance, if any, are independently selected from the group consisting of hydrogen, alkyl, phenyl, halogen, substituted phenyl. In one embodiment, each R is methoxy, ethoxy or propoxy. In another embodiment at least two R groups are alkylalkoxy groups wherein the alkyl moiety is C₁ to C₄ alkyl and the alkoxy moiety is C₁ to C₆ alkoxy. In yet another embodiment for a vapor phase precursor, at least two R groups are ether-alkoxy groups of the formula (C₁ to C₆ alkoxy)ₙ wherein n is 2 to 6.

Suitable silicon containing prepolymers include, for example, any or a combination of alkoxysilanes such as tetraethoxysilane, tetrapropoxysilane, tetraisopropoxysilane, tetra(methoxyethoxy)silane, tetra(methoxyethoxyethoxy)silane which have four groups which may be hydrolyzed and than condensed to produce silica, alkylalkoxysilanes such as methyltriethoxysilane silane, arylalkoxysilanes such as phenyltriethoxysilane and precursors such as triethoxysilane which yield SiH functionality to the film. Tetrakis(methoxyethoxyethoxy)silane, tetrakis(ethoxyethoxy)silane, tetrakis(butoxyethoxyethoxy)silane, tetrakis(2-ethylthoxy)silane, tetrakis(methoxyethoxy)silane, and tetrakis(methoxypropoxy)silane are particularly useful for the invention.

In a still further embodiment of the invention, the alkoxysilane compounds described above may be replaced, in whole or in part, by compounds with acetoxy and/or halogen-based leaving groups. For example, the prepolymer may be an acetoxy (CH₃—CO—O—) such as an acetoxy-silane compound and/or a halogenated compound, e.g., a halogenated silane compound and/or combinations thereof. For the halogenated prepolymers the halogen is, e.g., Cl, Br, I and in certain aspects, will optionally include F. Suitable acetoxy-derived prepolymers include, e.g., tetraacetoxysilane, methyltriacetoxysilane and/or combinations thereof.

In one embodiment of the invention, the silicon containing prepolymer includes a monomer or polymer precursor, such as acetoxysilane, an ethoxysilane, methoxysilane and/or combinations thereof. In another embodiment of the invention, the silicon containing prepolymer includes a tetraacetoxysilane, a C, to about C₆ alkyl or aryl-triacetoxysilane and combinations thereof. In another embodiment, the triacetoxysilane is a methyltriacetoxysilane.

In one embodiment of the invention the silicon containing prepolymer is present in the overall composition of the invention in an amount of from about 10 weight percent to about 80 weight percent, in another embodiment from about 20 weight percent to about 70 weight percent, and in another embodiment from about 25 weight percent to about 65 weight percent.

The prepolymer may optionally be mixed with water. In one embodiment, the overall composition of the invention may comprise water, in either liquid or water vapor form. For example, the overall composition may be applied to a substrate and then exposed to an ambient atmosphere that includes water vapor at standard temperatures and standard atmospheric pressure. Optionally, the composition is prepared prior to application to a substrate to include water in a proportion suitable for initiating aging of the precursor composition, without being present in a proportion that results in the precursor composition aging or gelling before it can be applied to a desired substrate. By way of example, when water is mixed into the precursor composition it is present in a proportion wherein the composition comprises water in a molar ratio of water to Si atoms in the silicon containing prepolymer ranging from about 0.1:1 to about 50:1. In another embodiment, it ranges from about 0.1:1 to about 10:1 and in still another embodiment from about 0.5:1 to about 1.5:1.

The silicon containing pre-polymer is combined with at least one porogen, and at least one metal-ion-free catalyst, to thereby form a composition. The porogen may be a compound or oligomer or polymer and is selected such that, when it is removed, e.g., by the application of heat, a silica dielectric film is produced that has a nanometer scale porous structure. The scale of the pores produced by porogen removal is proportional to the effective steric diameters of the selected porogen component. The need for any particular pore size range (i.e., diameter) is defined by the scale of the semiconductor device in which the film is employed. Furthermore, the porogen should not be so small as to result in the collapse of the produced pores, e.g., by capillary action within such a small diameter structure, resulting in the formation of a non-porous (dense) film. Further still, there should be minimal variation in diameters of all pores in the pore population of a given film. The porogen should comprise a compound that has a substantially homogeneous molecular weight and molecular dimension, and not a statistical distribution or range of molecular weights, and/or molecular dimensions, in a given sample. The avoidance of any significant variance in the molecular weight distribution allows for a substantially uniform distribution of pore diameters in the film treated by the inventive processes. If the produced film has a wide distribution of pore sizes, the likelihood is increased of forming one or more large pores, i.e., bubbles, that could interfere with the production of reliable semiconductor devices.

Furthermore, the porogen should have a molecular weight and structure such that it is readily and selectively removed from the film without interfering with film formation. This is based on the nature of semiconductor devices, which typically have an upper limit to processing temperatures. Broadly, a porogen should be removable from the newly formed film at temperatures below, e.g., about 450° C. In particular embodiments, depending on the desired post film formation fabrication process and materials, the porogen is selected to be readily removed at temperatures ranging from about 150° C. to about 450° C. during a time period ranging, e.g., from about 30 seconds to about 60 minutes. The removal of the porogen may be induced by heating the film at or above atmospheric pressure or under a vacuum, or by exposing the film to radiation, or both.

Porogens which meet the above characteristics include those compounds and polymers which have a boiling point, sublimation temperature, and/or decomposition temperature (at atmospheric pressure) range, for example, from about 150° C. to about 450° C. In addition, porogens suitable for use according to the invention include those having a molecular weight ranging, for example, from about 100 to about 50,000 amu, and in another embodiment the molecular weight ranges from about 100 to about 3,000 amu.

Porogens suitable for use in the processes and compositions of the invention include polymers, particularly those which contain one or more reactive groups, such as hydroxyl or amino. Within these general parameters, a suitable polymer porogen for use in the compositions and methods of the invention is, e.g., a polyalkylene oxide, a monoether of a polyalkylene oxide, a diether of a polyalkylene oxide, bisether of a polyalkylene oxide, an aliphatic polyester, an acrylic polymer, an acetal polymer, a poly(caprolactone), a poly(valeractone), a poly(methyl methacrylate), a poly (vinylbutyral) and/or combinations thereof. When the porogen is a polyalkylene oxide monoether, one particular embodiment is a C₁ to about C₆ alkyl chain between oxygen atoms and a C₁ to about C₆ alkyl ether moiety, and wherein the alkyl chain is substituted or unsubstituted, e.g., polyethylene glycol monomethyl ether, polyethylene glycol dimethyl ether, or polypropylene glycol monomethyl ether.

Other useful porogens are porogens that do not bond to the silicon containing pre-polymer, and include a poly(alkylene)diether, a poly(arylene)diether, poly(cyclic glycol)diether, Crown ethers, polycaprolactone, fully end-capped polyalkylene oxides, fully end-capped polyarylene oxides, polynorbene, and combinations thereof.

In one embodiment, the porogen does not bond to the silicon containing pre-polymer. Suitable porogens which do not bond to the silicon containing pre-polymer include poly(ethylene glycol)dimethyl ethers, poly(ethylene glycol) bis(carboxymethyl)ethers, poly(ethylene glycol) dibenzoates, poly(ethylene glycol) diglycidyl ethers, a poly(propylene glycol) dibenzoates, poly(propylene glycol) diglycidyl ethers, poly(propylene glycol)dimethyl ether, 15-Crown 5, 18-Crown-6, dibenzo-18-Crown-6, dicyclohexyl-18-Crown-6, dibenzo-15-Crown-5 and combinations thereof.

The porogen should be present in the overall composition in an amount ranging from about 1 to about 50 weight percent, or more. In one embodiment, the porogen is present in the composition in an amount ranging from about 2 to about 20 weight percent, and in another embodiment it is present in an amount of from about 3 weight percent to about 19 weight percent.

The metal-ion-free catalyst is selected from the group consisting of onium compounds and nucleophiles. The catalyst may be, for example an ammonium compound, an amine, a phosphonium compound or a phosphine compound. Non-exclusive examples of such include tetraorganoammonium compounds and tetraorganophosphonium compounds including tetramethylammonium acetate, tetramethylammonium hydroxide, tetrabutylammonium acetate, triphenylamine, trioctylamine, tridodecylamine, triethanolamine, tetramethylphosphonium acetate, tetramethylphosphonium hydroxide, triphenylphosphine, trimethylphosphine, trioctylphosphine, and combinations thereof. The composition may further comprise a non-metallic, nucleophilic additive which accelerates the crosslinking of the composition. These include dimethyl sulfone, dimethyl formamide, hexamethylphosphorous triamide (HMPT), amines and combinations thereof. The catalyst should be present in the overall composition in an amount of from about 1 ppm by weight to about 1000 ppm. In another embodiment of the invention, the catalyst is present in the overall composition in an amount of from about 6 ppm to about 200 ppm.

The composition may also comprise additional components such as adhesion promoters, antifoam agents, detergents, flame retardants, pigments, plasticizers, stabilizers, and surfactants. The present composition has utility in non-microelectronic applications such as thermal insulation, encapsulant, matrix materials for polymer and ceramic composites, light weight composites, acoustic insulation, anti-corrosive coatings, binders for ceramic powders, and fire retardant coatings.

Next, a layer of the composition is applied onto a substrate. The present films may be formed on various substrates. The term “substrate” as used herein includes any suitable material or composition formed before a nanoporous silica film of the invention is applied to and/or formed on that material or composition.

Suitable substrates nonexclusively include glass, ceramic, plastic, metal or coated metal, or composite material. For example, the substrate may comprise a semiconductor material such as silicon or gallium arsenide die or wafer surface, a packaging surface such as found in a copper, silver, nickel or gold plated leadframe, a copper surface such as found in a circuit board or package interconnect trace, a via-wall or stiffener interface (“copper” includes considerations of bare copper and its oxides), and/or a polymer-based packaging or board interface such as found in a polyimide-based flex package, lead or other metal alloy solder ball surface, glass and polymers. Substrates may also include silicon, silicon nitride, silicon oxide, silicon oxycarbide, silicon dioxide, silicon carbide, silicon oxynitride, titanium nitride, tantalum nitride, tungsten nitride, aluminum, copper, tantalum, organosiloxanes, organo silicon glass, and fluorinated silicon glass.

On the surface of the substrate there may be an optional pattern of raised lines, such as metal, oxide, nitride or oxynitride lines which are formed by well known lithographic techniques. Suitable materials for the lines include silica, silicon nitride, titanium nitride, tantalum nitride, aluminum, aluminum alloys, copper, copper alloys, tantalum, tungsten and silicon oxynitride. Useful metallic targets for making these lines are taught in commonly assigned U.S. Pat. Nos. 5,780,755; 6,238,494; 6,331,233; and 6,348,139 and are commercially available from Honeywell International Inc. These lines form the conductors or insulators of an integrated circuit. Such are typically closely separated from one another at distances of about 20 micrometers or less. In another embodiment, the lines are separated by 1 micrometer or less, and in yet another embodiment from about 0.05 to about 1 micrometer. Other optional features of the surface of a suitable substrate include an oxide layer, such as an oxide layer formed by heating a silicon wafer in air or, more particularly, an SiO₂ oxide layer formed by chemical vapor deposition of such art-recognized materials as, e.g., plasma enhanced tetraethoxysilane oxide (“PETEOS”), plasma enhanced silane oxide (“PE silane”) and combinations thereof, as well as one or more previously formed nanoporous silica dielectric films.

The composition layer may be applied onto the substrate so as to cover and/or lie between such optional electronic surface features, e.g., circuit elements and/or conduction pathways that may have been previously formed features of the substrate. Such optional substrate features may also be applied above a nanoporous silica film of the invention in the form of at least one additional layer, so that the low dielectric film serves to insulate one or more electrically and/or electronically functional layers of the resulting integrated circuit. Such nanoporous silica dielectric film may have a void volume of about 30% or less based on the total volume of the nanoporous silica dielectric film, and may have a dielectric constant of about 2.2 or less. Thus, a substrate according to the invention optionally includes a silicon material that is formed over or adjacent to a nanoporous silica film of the invention, during the manufacture of a multilayer and/or multi-component integrated circuit. A substrate according to the invention optionally comprise a semiconductor material such as silicon, gallium arsenide, silicon nitride, silicon oxide, silicon oxycarbide, silicon dioxide, silicon carbide, silicon oxynitride, titanium nitride, tantalum nitride, tungsten nitride, aluminum, copper, tantalum, organosiloxanes, organo silicon glass, fluorinated silicon glass or combinations thereof. In a further embodiment, a substrate bearing a nanoporous silica film or films may have a void volume of about 30% or less based on the total volume of the nanoporous silica dielectric film, a dielectric constant of about 2.2 or less, and can be further covered with any art known non-porous insulation layer, such as a glass cap layer or the like. In another embodiment, a substrate may have metallic lines on the surface of the substrate.

The composition layer may be coated onto the substrate by any suitable solution technique, nonexclusively including spraying, rolling, dipping, brushing, spin coating, flow coating, or casting, and chemical vapor deposition, or the like, with spin coating being preferred for microelectronics. Prior to application of the composition layer, the substrate surface may optionally be prepared for coating by standard, art-known cleaning methods. For chemical vapor deposition (CVD), the composition is placed into an CVD apparatus, vaporized, and introduced into a deposition chamber containing the substrate to be coated. Vaporization may be accomplished by heating the composition above its vaporization point, by the use of a vacuum, or by a combination of the above. Generally, vaporization is accomplished at temperatures in the range of 50° C.-300° C. under atmospheric pressure or at lower temperature (near room temperature) under vacuum.

CVD processes as discussed here may include atmospheric pressure CVD (APCVD), low pressure CVD (LPCVD), plasma enhanced CVD (PECVD), and high density plasma enhanced CVD (HDPCVD). Each of these approaches had advantages and disadvantages. APCVD devices operate in a mass transport limited reaction mode at temperatures of approximately 400° C. In mass-transport limited deposition, temperature control of the deposition chamber is less critical than in other methods because mass transport processes are only weakly dependent on temperature. As the arrival rate of the reactants is directly proportional to their concentration in the bulk gas, maintaining a homogeneous concentration of reactants in the bulk gas adjacent to the wafers is critical. Thus, to insure films of uniform thickness across a wafer, reactors that are operated in the mass transport limited regime must be designed so that all wafer surfaces are supplied with an equal flux of reactant. The most widely used APCVD reactor designs provide a uniform supply of reactants by horizontally positioning the wafers and moving them under a gas stream.

In contrast to APCVD reactors, LPCVD reactors operate in a reaction rate-limited mode. In processes that are run under reaction rate-limited conditions, the temperature of the process is an important parameter. To maintain a uniform deposition rate throughout a reactor, the reactor temperature must be homogeneous throughout the reactor and at all wafer surfaces. Under reaction rate-limited conditions, the rate at which the deposited species arrive at the surface is not as critical as constant temperature. Thus, LPCVD reactors do not have to be designed to supply an invariant flux of reactants to all locations of a wafer surface.

Under the low pressure of an LPCVD reactor, for example, operating at medium vacuum (30-250 Pa or 0.25-2.0 torr) and higher temperature (550-600° C.), the diffusivity of the deposited species is increased by a factor of approximately 1000 over the diffusivity at atmospheric pressure. The increased diffusivity is partially offset by the fact that the distance across which the reactants must diffusive increases by less than the square root of the pressure. The net effect is that there is more than an order of magnitude increase in the transport of reactants to the substrate surface and by-products away from the substrate surface.

LPCVD reactors are designed in two primary configurations: (a) horizontal tube reactors; and (b) vertical flow isothermal reactors. Horizontal tube, hot wall reactors are the most widely used LPCVD reactors in VLSI processing. They are employed for depositing poly-Si, silicon nitride, and undoped and doped SiO₂ films. They find such broad applicability primarily because of their superior economy, throughput, uniformity, and ability to accommodate large diameter, e.g., 150 mm, wafers.

The vertical flow isothermal LPCVD reactor further extends the distributed gas feed technique so that each wafer receives an identical supply of fresh reactants. Wafers are again stacked side by side, but are placed in perforated-quartz cages. The cages are positioned beneath long, perforated, quartz reaction-gas injector tubes, one tube for each reactant gas. Gas flows vertically from the injector tubes, through the cage perforations, past the wafers, parallel to the wafer surface and into exhaust slots below the cage. The size, number, and location of cage perforations are used to control the flow of reactant gases to the wafer surfaces. By properly optimizing cage perforation design, each wafer may be supplied with identical quantities of fresh reactants from the vertically adjacent injector tubes. Thus, this design may avoid the wafer-to-wafer reactant depletion effects of the end-feed tube reactors, requires no temperature ramping, produces highly uniform depositions, and reportedly achieves low particulate contamination.

The third major CVD deposition method is PECVD. This method is categorized not only by pressure regime, but also by its method of energy input. Rather than relying solely on thermal energy to initiate and sustain chemical reactions, PECVD uses an RF-induced glow discharge to transfer energy into the reactant gases, allowing the substrate to remain at a lower temperature than in APCVD or LPCVD processes. Lower substrate temperature is the major advantages of PECVD, providing film deposition on substrates not having sufficient thermal stability to accept coating by other methods. PECVD may also enhance deposition rates over those achieved using thermal reactions. Moreover, PECVD may produce films having unique compositions and properties. Desirable properties such as good adhesion, low pinpole density, good step coverage, adequate electrical properties, and compatibility with fine-line pattern transfer processes, have led to application of these films in VLSI.

PECVD requires control and optimization of several deposition parameters, including rf power density, frequency, and duty cycle. The deposition process is dependent in a complex and interdependent way on these parameters, as well as on the usual parameters of gas composition, flow rates, temperature, and pressure. Furthermore, as with LPCVD, the PECVD method is surface reaction limited, and adequate substrate temperature control is thus necessary to ensure uniform film thickness.

CVD systems usually contain the following components: gas sources, gas feed lines, mass-flow controllers for metering the gases into the system, a reaction chamber or reactor, a method for heating the wafers onto which the film is to be deposited, and in some types of systems, for adding additional energy by other means, and temperature sensors. LPCVD and PECVD systems also contain pumps for establishing the reduced pressure and exhausting the gases from the chamber.

Next, the composition layer is cross-linked to produce a gelled film. Those skilled in the art will appreciate that specific temperature ranges for crosslinking and porogen removal from the nanoporous dielectric films will depend on the selected materials, substrate and desired nanoscale pore structure, as is readily determined by routine manipulation of these parameters. Generally, the coated substrate is subjected to a treatment such as heating to effect crosslinking of the composition on the substrate to produce a gelled film.

Crosslinking may be done by heating the film at a temperature ranging from about 100° C. to about 250° C., for a time period ranging from about 30 seconds to about 10 minutes to gel the film. Additional curing methods include the application of sufficient energy to cure the film by exposure of the film to electron beam energy, ultraviolet energy, microwave energy, and the like, according to art-known methods.

Next, the gelled film is heated at a temperature and for a duration sufficient to remove substantially all of said porogen to thereby produce a nanoporous silica dielectric film. The porogen should be sufficiently non-volatile so that it does not evaporate from the film before the film solidifies. The gelled film should be heated at a temperature ranging from about 150° C. to about 450° C. In another embodiment, it is heated from about 150° C. to about 350° C. for a time period ranging from about 30 seconds to about 1 hour. An important feature of the invention is that the step (d) crosslinking should be conducted at a temperature that is less than the heating temperature of step (e).

The nanoporous silica dielectric film may have a void volume of about 30% or less based on the total volume of the nanoporous silica dielectric film. The nanoporous silica dielectric film of the invention may have a dielectric constant of about 2.2 or less. In one particular embodiment, the nanoporous silica dielectric film ranges from about 1.85 to about 2.19.

The nanoporous silica dielectric film formed according to the invention should have an average pore diameter in the range of from about 1 nm to about 30 nm. In one embodiment of the invention, the pore diameter ranges from about 1 nm to about 10 nm and in another embodiment it ranges from about 1 nm to about 6 nm. In another embodiment, the invention comprises a nanoporous dielectric film having a void volume of about 30% or less based on the total volume of the nanoporous silica dielectric film, and having a dielectric constant of about 2.2 or less. In another embodiment, the invention comprises a nanoporous dielectric film having a void volume of about 30% or less based on the total volume of the nanoporous silica dielectric film, and having a dielectric constant of about 2.2 or less and having pore diameter ranges from about 1 nm to about 30 nm. In another embodiment, the invention comprises a nanoporous dielectric film having a void volume of about 30% or less based on the total volume of the nanoporous silica dielectric film, and having a dielectric constant of about 2.2 or less and having pore diameter ranges from about 1 nm to about 10 nm.

In an additional embodiment of the invention, a layer of a photoresist is deposited onto the nanoporous silica dielectric film, and a portion of the photoresist over some areas of the film is imagewise removed to form a pattern. The photoresist may be positive working or negative working, and photoresist materials are generally commercially available. Suitable positive working photoresists are well known in the art and may comprise an o-quinone diazide radiation sensitizer. The o-quinone diazide sensitizers include the o-quinone-4- or -5-sulfonyl-diazides disclosed in U.S. Pat. Nos. 2,797,213; 3,106,465; 3,148,983; 3,130,047; 3,201,329; 3,785,825; and 3,802,885. When o-quinone diazides are used, particularly suitable binding resins include a water insoluble, aqueous alkaline soluble or swellable binding resin, such as a novolak. Suitable positive photoresists may be obtained commercially.

The imagewise removal of portions of the photoresist should be performed in a manner well known in the art such as by imagewise exposing the photoresist to actinic radiation such as through a suitable mask and developing the photoresist. The photoresist may be imagewise exposed to actinic radiation such as light in the visible, ultraviolet or infrared regions of the spectrum through a mask, or scanned by an electron beam, ion or neutron beam or X-ray radiation. Actinic radiation may be in the form of incoherent light or coherent light, for example, light from a laser. The photoresist is then imagewise developed using a suitable solvent, such as an aqueous alkaline solution. Optionally the photoresist is heated to cure the image portions thereof and thereafter developed to remove the nonimage portions and define a via mask.

Next a dry etch treatment of the nanoporous silica dielectric film is conducted such that areas of the film under the removed portion of the photoresist are removed to form at least one via or trench through the nanoporous silica dielectric film. The at least one via and/or trench defines sidewalls and a floor. Dry etching treatments are known by those skilled in the art, and any known dry etching process may be used in accordance with the present invention. In a typical dry etching process, a substrate is immersed in a reactive gas (plasma). A layer to be etched is removed by chemical reactions and/or by physical means such as ion bombardment. The reaction products are volatile and are carried away in the gas stream.

A dry ashing treatment is then conducted to remove any remaining photoresist from the film and any etch residue from the walls and floor of the trench and/or via. Such dry ashing is well known in the art. In a conventional dry ashing process, an oxygen plasma treatment is used. Oxygen atom radicals, neutral particles dissociated from O₂ (oxygen) plasma generated by using microwaves or radio frequencies (RF) are chemically reacted with a resist to thereby remove the resist. Typical ashing apparatuses for such dry ashing processes may include barrel-type RF plasma ashing apparatuses and downflow-type ashing apparatuses.

The invention provides a nanoporous silica dielectric film, having a void volume of about 30% or less based on the total volume of the nanoporous silica dielectric film, having a dielectric constant of about 2.2 or less, and patterned to have formed at least one via and/or trench therein. It may further comprise a coating material in at least one via and/or trench. Suitable coating materials nonexclusively include anti-reflective coating (ARC) materials, preferably inorganic anti-reflective coating materials, such as those described in U.S. Pat. Nos. 6,268,457; 6,365,765 and 6,506,497; and hydrogen silsesquioxane and methyl silsesquioxane and metals such as Ta and TaN. Such coating materials may be deposited into the at least one via and/or trench by any suitable conventional method such as spin coating or any other methods suitable for deposition, including, for example, CVD, PVD and ALD.

The invention provides a method for making a nanoporous silica dielectric film, having a void volume of about 30% or less based on the total volume of the nanoporous silica dielectric film, having a dielectric constant of about 2.2 or less, and patterned to have formed at least one via and/or trench therein. The method may further comprise a step of applying a coating material in at least one via and/or trench. Suitable coating materials nonexclusively include anti-reflective coating (ARC) materials, preferably inorganic anti-reflective coating materials, such as those described in U.S. Pat. Nos. 6,268,457; 6,365,765 and 6,506,497; and hydrogen silsesquioxane and methyl silsesquioxane and metals such as Ta and TaN. The method may further comprise depositing such coating materials into the at least one via and/or trench by any suitable conventional method such as spin coating or any other methods suitable for deposition, including, for example, CVD, PVD and ALD.

The methods and compositions of the present invention may be used to produce various nanoporous dielectric film containing devices, semiconductor devices, and the like. In particular, the nanoporous silica dielectric films of the present invention or formed according to the present invention may be used in microelectronic applications, such as for dielectric substrate materials in microchips, multichip modules, laminated circuit boards, or printed wiring boards. They may also be used in electrical devices and more specifically, as an interlayer dielectric in an interconnect associated with a single integrated circuit (“IC”) chip. An integrated circuit chip typically has on its surface a plurality of layers of the present composition and multiple layers of metal conductors. It may also include regions of the present composition between discrete metal conductors or regions of conductor in the same layer or level of an integrated circuit. The present nanoporous silica dielectric films may also be used as an etch stop or hardmask layer. The films of the present invention may further be used in dual damascene (such as copper) processing and substractive metal (such as aluminum or aluminum/tungsten) processing for integrated circuit manufacturing. The present composition may be used in a desirable all spin-on stacked film as disclosed by Michael E. Thomas, “Spin-On Stacked Films for Low k_{eff} Dielectrics”, Solid State Technology (July 2001), incorporated herein in its entirety by reference. The present composition may be used in an all spin-on stacked film having additional dielectrics such as taught by U.S. Pat. Nos. 6,268,457; 5,986,045; 6,124,411; and 6,303,733.

The following non-limiting examples serve to illustrate the invention. It will be appreciated that variations in proportions and alternatives in elements of the components of the invention will be apparent to those skilled in the art and are within the scope of the present invention.

### EXAMPLE 1

This example shows the production of a silica containing pre-polymer capable of forming a film with a dielectric constant of 3.2 and higher.

A precursor was prepared by combining, in a 100 ml round bottom flask (containing a magnetic stirring bar), 10 g tetraacetoxysilane, 10 g methyltriacetoxysilane, and 19 g propylene glycol methyl ethyl acetate (PGMEA). These ingredients were combined within an N₂-environment (N₂ glove bag). The flask was also connected to an N₂ environment to prevent environmental moisture from entering the solution (standard temperature and pressure).

The reaction mixture was heated to 80° C. before 1.5 g of water was added to the flask. After the water addition is complete, the reaction mixture was allowed to cool to ambient before 0.10 g of tetraorganoammonium (TMAA) were added. The reaction mixture was stirred for another 2 hrs before the resulting solution was filtered through a 0.2 micron filter to provide the precursor solution masterbatch for the next step. The solution is then deposited onto a series of 8-inch silicon wafers, each on a spin chuck and spun at 1000 rpm for 15 seconds. The presence of water in the precursor resulted in the film coating being substantially condensed by the time that the wafer was inserted into the first hot-plate. Insertion into the first hot-plate, as discussed below, takes place within the 10 seconds of the completion of spinning. Each coated wafer was then transferred into a sequential series of hot-plates preset at specific temperatures, for one minute each. In this example, there are three hot-plates, and the preset hot-plate temperatures were 125° C., 200° C., and 350° C., respectively. Each wafer is cooled after receiving the three-hot-plate stepped heat treatment, and the produced dielectric film was measured using ellipsometry to determine its thickness and refractive index. The film has a bake thickness of 5389 Å, a bake refractive index of 1.40±0.01. Each film-coated wafer is then further cured at 425° C. for one hour under flowing nitrogen to produce a film with a cure thickness of 5315 Å and a cure refractive index of 1.39±0.01 (see entry 1 of Table I).

### EXAMPLE 2

This example shows the production of a nanoporous silica with a porogen having a high porosity from a silica containing pre-polymer capable of forming a film with a dielectric constant of 3.2 and higher.

Crude PEO (polyethylene glycol methyl ether MW=550) with high concentration of sodium was purified by mixing the crude PEO with water in a 50:50 weight ratio. This mixture was passed through an ion exchange resin to remove metals. The filtrate was collected and subjected to vacuum distillation to remove water to produce neat, low metal PEO(with <100 ppb Na).

The procedure of Example 1 was then followed with the PEO added to the masterbatch. Thereafter, the resulting solution was filtered through a 0.2 micron filter to provide the precursor solution. The solution was then deposited onto a series of 8-inch silicon wafers, each on a spin chuck and spun at 2000 rpm for 15 seconds. The presence of water in the precursor resulted in the film coating being substantially condensed by the time that the wafer was inserted into the first oven. Insertion into the first oven, as discussed below, took place within the 10 seconds of the completion of spinning. Each coated wafer was then transferred into a sequential series of ovens preset at specific temperatures, for one minute each. In this example, there are three ovens, and the preset oven temperatures were 125° C., 200° C., and 350° C., respectively. The PEO was driven off by these sequential heating steps as each wafer was moved through each of the three respective ovens. Each wafer was cooled after receiving the three-oven stepped heat treatment, and the produced dielectric film was measured using ellipsometry to determine its thickness and refractive index. Each film-coated wafer was then further cured at 425° C. for one hour under flowing nitrogen. The film has a cure thickness of 5452 Å and a cure refractive index of 1.224. In the table, capacitance of the film was measured under ambient conditions (room temperature and humidity). Dielectric constant based on ambient capacitance value is called kambient. The capacitance of the film was measured again after heating the wafer in a hot plate at 200° C. for 2 minutes in order to drive off adsorbed moisture. The cured film produced has a k_{de-gas} of about 2.28 (see entry 1 of Table II). It is estimated that from a k value of 2.28, the film has 45% porosity. When the film is immersed in ACT®NE-89 (an organo-amine based etchant), most of the film was etched away after 2 min to give a removal rate of greater than 4000 Å/min.

### EXAMPLE 3

This example shows the production of a silica containing pre-polymer capable of forming a film with a dielectric constant of 2.8.

A precursor was prepared by combining, in a 100 ml round bottom flask (containing a magnetic stirring bar), 50 g methyltriacetoxysilane, and 30 g propylene glycol methyl ethyl acetate (PGMEA). These ingredients were combined within an N₂-environment (N₂ glove bag). The reaction mixture was stirred for 10 minutes before 4.23 g of water was added to the flask. After the water addition is complete, the reaction mixture was allowed to cool to ambient before 0.28 g of tetraorganoammonium (TMAA, 1% in acetic acid)) were added. The reaction mixture was stirred for another 2 hrs before the resulting solution was filtered through a 0.2 micron filter to provide the precursor solution masterbatch for the next step. The solution is then deposited onto a series of 8-inch silicon wafers, each on a spin chuck and spun at 1750 rpm for 15 seconds. The presence of water in the precursor resulted in the film coating being substantially condensed by the time that the wafer was inserted into the first hot-plate. Insertion into the first hot-plate, as discussed below, takes place within the 10 seconds of the completion of spinning. Each coated wafer was then transferred into a sequential series of hot-plates preset at specific temperatures, for one minute each. In this example, there are three hot-plates, and the preset hot-plate temperatures were 125° C., 200° C., and 350° C., respectively. Each wafer is cooled after receiving the three-hot-plate stepped heat treatment, and the produced dielectric film was measured using ellipsometry to determine its thickness and refractive index. The film has a bake thickness of 6243 Å, a bake refractive index of 1.39±0.01. Each film-coated wafer is then further cured at 425° C. for one hour under flowing nitrogen to produce a film with a cure thickness of 6245 Å and a cure refractive index of 1.38±0.01. The cured film produced has a k_{de-gas} of about 2.79 (see entry 2 of Table I).

### EXAMPLE 4

This example shows the production of a nanoporous silica with a porogen having a low porosity from a silica containing pre-polymer capable of forming a film with a dielectric constant of 2.8.

Crude DMEPEO (polyethylene glycol dimethyl ether MW=500) with high concentration of sodium was purified by mixing the crude DMEPEO with water in a 50:50 weight ratio. This mixture was passed through an ion exchange resin to remove metals. The filtrate was collected and subjected to vacuum distillation to remove water to produce neat, low metal DMEPEO (with <100 ppb Na).

A precursor was prepared by combining, in a 100 ml round bottom flask (containing a magnetic stirring bar), 50 g methyltriacetoxysilane, and 30 g propylene glycol methyl ethyl acetate (PGMEA). These ingredients were combined within an N₂-environment (N₂ glove bag). The reaction mixture was stirred for 10 minutes before 4.23 g of water was added to the flask. After the water addition is complete, the reaction mixture was allowed to cool to ambient before 0.28 g of tetraorganoammonium (TMAA, 1% in acetic acid) were added. The reaction mixture was stirred for another 2 hrs before DMEPEO (7.05 g) was then added. The resulting reaction mixture was stirred for another 2 h before it was filtered through a 0.2 micron filter to provide the precursor solution. The solution is then deposited onto a series of 8-inch silicon wafers, each on a spin chuck and spun at 1750 rpm for 15 seconds. The presence of water in the precursor resulted in the film coating being substantially condensed by the time that the wafer was inserted into the first hot-plate. Insertion into the first hot-plate, as discussed below, takes place within the 10 seconds of the completion of spinning. Each coated wafer was then transferred into a sequential series of hot-plates preset at specific temperatures, for one minute each. In this example, there are three hot-plates, and the preset hot-plate temperatures were 125° C., 200° C., and 350° C., respectively. The DMEPEO was driven off by these sequential heating steps as each wafer was moved through each of the three respective ovens. Each wafer is cooled after receiving the three-hot-plate stepped heat treatment, and the produced dielectric film was measured using ellipsometry to determine its thickness and refractive index. The film has a bake thickness of 8523 Å, a bake refractive index of 1.28±0.01. Each film-coated wafer is then further cured at 425° C. for one hour under flowing nitrogen to produce a film with a cure thickness of 8254 Å and a cure refractive index of 1.28±0.01. The cured film produced has a k_{de-gas} of about 2.27 (see entry 2 of Table II). It is estimated that from a k value of 2.27, the film has 29% porosity. When the film is immersed in ACT®NE-89 (an organo-amine based etchant), only a small amount of the film was etched away after 2 min to give a removal rate of 122 Å/min.

TABLE I
Properties of Dense Silica

| Entry | K | Cured R.I. | Cured Thickness Å |
|---|---|---|---|
| 1 | 3.48 | 1.39 | 5315 |
| 2 | 2.79 | 1.38 | 6245 |

TABLE II
Properties of Porous Silica

| | | | Entry 2 |
|---|---|---|---|
| | | Entry 1 | New Porous |
| Properties | | NANOGLASS ® E | Methylsiloxane |
| Thickness-cured (Å) | | 5452 | 8254 |
| Refractive Index-cured | | 1.224 | 1.277 |
| k_{ambient} | | 2.54 | 2.30 |
| k_{de-gas} | | 2.28 | 2.27 |
| Modulus (GPa) | | 3.53 +/− 0.30 | 2.83 ± 0.17 |
| Hardness (GPa) | | 0.37 +/− 0.03 | 0.41 ± 0.04 |
| Wet Etch | Etch time | 2 min | 2 min |
| (ACT ® NE-89) | Etch rate | >2000 Å/min | 122 Å/min |

While the present invention has been particularly shown and described with reference to preferred embodiments, it will be readily appreciated by those of ordinary skill in the art that various changes and modifications may be made without departing from the spirit and scope of the invention. It is intended that the claims be interpreted to cover the disclosed embodiment, those alternatives which have been discussed above and all equivalents thereto.

1. A method of producing a nanoporous silica dielectric film comprising:
(a) providing a silicon containing pre-polymer capable of forming a film with a dielectric constant of about 2.8 or less, which pre-polymer is optionally mixed with water; thereafter
(b) combining the result of (a) with a porogen, and a metal-ion-free catalyst selected from the group consisting of onium compounds and nucleophiles, to thereby form a composition; then
(c) coating a layer of the composition onto substrate; then
(d) crosslinking the composition to produce a gelled film, and then
(e) heating the gelled film at a temperature and for a duration effective to remove substantially all of said porogen to thereby produce a nanoporous silica dielectric film having a void volume of about 30% or less based on the total volume of the nanoporous silica dielectric film, and having a dielectric constant of about 2.2 or less.

2. The method of claim 1 which further comprises the subsequent steps of:
(f) depositing a layer of a photoresist onto the nanoporous silica dielectric film, and imagewise removing a portion of the photoresist over some areas of the film to form a pattern;
(g) conducting a dry etch treatment of the nanoporous silica dielectric film such that areas of the film under the removed portion of the photoresist form at least one via or trench through the nanoporous silica dielectric film, said at least one via and/or trench defining sidewalls and a floor;
(h) conducting a dry ash treatment such that the remainder of the photoresist is removed; and
(i) depositing an anti-reflective coating material into the at least one via and/or trench.

3. The method of claim 1 wherein the step (d) crosslinking is conducted at a temperature which is less than the heating temperature of step (e).

4. The method of claim 1 wherein step (d) comprises heating the film at a temperature ranging from about 100° C. to about 250° C., for a time period ranging from about 30 seconds to about 10 minutes.

5. The method of claim 1 wherein step (e) comprises heating the film at a temperature ranging from about 150° C. to about 450° C., for a time period ranging from about 30 seconds to about 1 hour.

6. The method of claim 1 wherein the nanoporous silica dielectric film has an average pore diameter in the range of from about 1 nm to about 30 nm.

7. The method of claim 1 wherein the composition comprises a silicon containing prepolymer of Formula I:
Rx-Si-Ly (Formula I)
wherein x is an integer ranging from 0 to about 2, and y is 4-x, an integer ranging from about 2 to about 4;
R is independently selected from the group consisting of alkyl, aryl, hydrogen, alkylene, arylene, and combinations thereof;
L is an electronegative moiety, independently selected from the group consisting of alkoxy, carboxy, amino, amido, halide, isocyanato and combinations thereof.

8. The method of claim 7 wherein the composition comprises a polymer formed by condensing a prepolymer according to Formula I, wherein the number average molecular weight of said polymer ranges from about 150 to about 300,000 amu.

9. The method of claim 1 wherein the composition comprises a silicon containing pre-polymer selected from the group consisting of an acetoxysilane, an ethoxysilane, a methoxysilane, and combinations thereof.

10. The method of claim 1 wherein the composition comprises a silicon containing pre-polymer selected from the group consisting of tetraacetoxysilane, a C, to about C₆ alkyl or aryl-triacetoxysilane, and combinations thereof.

11. The method of claim 10 wherein said triacetoxysilane is methyltriacetoxysilane.

12. The method of claim 1 wherein the composition comprises a silicon containing pre-polymer selected from the group consisting of tetrakis(2,2,2-trifluoroethoxy)silane, tetrakis(trifluoroacetoxy)silane, tetraisocyanatosilane, tris(2,2,2-trifluoroethoxy)methyl silane, tris(trifluoroacetoxy)methylsilane, methyltriisocyanatosilane and combinations thereof.

13. The method of claim 1 wherein the composition comprises water in a molar ratio of water to said Si atoms in said silicon containing prepolymer ranging from about 0.1:1 to about 50:1.

14. The method of claim 1 wherein the porogen is present in the composition in an amount of from about 1 to about 50 percent by weight of the composition.

15. The method of claim 1 further comprising an additional porogen wherein the additional porogen has a molecular weight ranging from about 100 to about 50,000 amu.

16. The method of claim 1 wherein the porogen is selected from the group consisting of a poly(alkylene)diether, a poly(arylene)diether, poly(cyclic glycol)diether, Crown ethers, polycaprolactone, fully end-capped polyalkylene oxides, fully end-capped polyarylene oxides, polynorbene, and combinations thereof.

17. The method of claim 1 wherein the porogen is selected from the group consisting of a poly(ethylene glycol)dimethyl ether, a poly(ethylene glycol) bis(carboxymethyl)ether, a poly(ethylene glycol) dibenzoate, a poly(ethylene glycol) propylmethyl ether, a poly(ethylene glycol) diglycidyl ether, a poly(propylene glycol) dibenzoate, a poly(propylene glycol) dibutyl ether, a poly(propylene glycol)dimethyl ether, a poly(propylene glycol) diglycidyl ether, 15-Crown 5, 18-Crown-6, dibenzo-18-Crown-6, dicyclohexyl-18-Crown-6, dibenzo-15-Crown-5 and combinations thereof.

18. The method of claim 1 further comprising an additional porogen wherein the additional porogen has a boiling point, sublimation point or decomposition temperature ranging from about 150° C. to about 450° C.

19. The method of claim 1 further comprising an additional porogen wherein the additional porogen comprises a reagent comprising at least one reactive hydroxyl or amino functional group, and said reagent is selected from the group consisting of an organic compound, an organic polymer, an inorganic polymer and combinations thereof.

20. The method of claim 1 further comprising an additional porogen wherein the additional porogen comprises a polyalkylene oxide monoether which comprises a C₁ to about C₆ alkyl chain between oxygen atoms and a C₁ to about C₆ alkyl ether moiety, and wherein the alkyl chain is substituted or unsubstituted.

21. The method of claim 20 wherein the polyalkylene oxide monoether is a polyethylene glycol monomethyl ether or polypropylene glycol monobutyl ether.

22. The method of claim 1 wherein the catalyst is selected from the group consisting of ammonium compounds, amines, phosphonium compounds, and phosphine compounds.

23. The method of claim 1 wherein the catalyst is selected from the group consisting of tetraorganoammonium compounds and tetraorganophosphonium compounds.

24. The method of claim 1 wherein the catalyst is selected from the group consisting of tetramethylammonium acetate, tetramethylammonium hydroxide, tetrabutylammonium acetate, triphenylamine, trioctylamine, tridodecylamine, triethanolamine, tetramethylphosphonium acetate, tetramethylphosphonium hydroxide, triphenylphosphine, trimethylphosphine, trioctylphosphine, and combinations thereof.

25. The method of claim 1 wherein the catalyst is selected from the group consisting of ammonium compounds, amines, phosphonium compounds, and phosphine compounds.

26. The method of claim 1 wherein the composition further comprises a nucleophilic additive which accelerates the crosslinking of the composition, which is selected from the group consisting of dimethyl sulfone, dimethyl form amide, hexamethylphosphorous triamide, amines and combinations thereof.

27. The method of claim 1 wherein the composition further comprises a solvent.

28. The method of claim 1 wherein the composition further comprises a solvent in an amount ranging from about 10 to about 95 percent by weight of the composition.

29. The method of claim 1 wherein the composition further comprises a solvent having a boiling, point ranging from about 50 to about 250° C.

30. The method of claim 1 wherein the composition further comprises a solvent selected from the group consisting of hydrocarbons, esters, ethers, ketones, alcohols, amides and combinations thereof.

31. The method of claim 30 wherein the solvent is selected from the group consisting of di-n-butyl ether, anisole, acetone, 3-pentanone, 2-heptanone, ethyl acetate, n-propyl acetate, n-butyl acetate, 2-propanol, dimethyl acetamide, propylene glycol methyl ether acetate, and combinations thereof.

32. A nanoporous dielectric film produced by a process comprising the steps of:
(a) providing a silicon containing pre-polymer capable of forming a film with a dielectric constant of about 2.8 or less, which pre-polymer is optionally mixed with water; thereafter
(b) combining the result of (a) with a porogen, and a metal-ion-free catalyst selected from the group consisting of onium compounds and nucleophiles, to thereby form a composition; then
(c) coating a layer of the composition onto substrate; then
(d) crosslinking the composition to produce a gelled film, and then
(e) heating the gelled film at a temperature and for a duration effective to remove substantially all of said porogen to thereby produce a nanoporous silica dielectric film having a void volume of about 30% or less based on the total volume of the nanoporous silica dielectric film, and having a dielectric constant of about 2.2 or less.

33. A semiconductor device comprising a nanoporous dielectric film of claim 32.

34. A semiconductor device of claim 33 that is an integrated circuit.

35. A nanoporous dielectric film-containing device produced by a process comprising the steps of:
(a) providing a silicon containing pre-polymer capable of forming a film with a dielectric constant of about 2.8 or less, which pre-polymer is optionally mixed with water; thereafter
(b) combining the result of (a) with a porogen, and a metal-ion-free catalyst selected from the group consisting of onium compounds and nucleophiles, to thereby form a composition; then
(c) coating a layer of the composition onto substrate; then
(d) crosslinking the composition to produce a gelled film, and then
(e) heating the gelled film at a temperature and for a duration effective to remove substantially all of said porogen to thereby produce a nanoporous silica dielectric film having a void volume of about 30% or less based on the total volume of the nanoporous silica dielectric film, and having a dielectric constant of about 2.2 or less;
(f) depositing a layer of a photoresist onto the nanoporous silica dielectric film, and imagewise removing a portion of the photoresist over some areas of the film to form a pattern;
(g) conducting a dry etch treatment of the nanoporous silica dielectric film such that areas of the film under the removed portion of the photoresist form at least one via or trench through the nanoporous silica dielectric film, said at least one via and/or trench defining sidewalls and a floor;
(h) conducting a dry ash treatment such that the remainder of the photoresist is removed; and
(i) depositing an anti-reflective coating material into the at least one via and/or trench.

36. A nanoporous silica dielectric film comprising a cured film containing substantially no porogen therein and having a void volume of about 30% or less based on the total volume of the nanoporous silica dielectric film, and having a dielectric constant of about 2.2 or less.

37. The nanoporous silica dielectric film of claim 36 which has an average pore diameter in the range of from about 1 nin to about 30 nm.

38. A microelectronic device which comprises a substrate and the nanoporous silica dielectric film of claim 36 on the substrate.

39. A microelectronic device of claim 38 comprising metallic lines on the surface of the substrate.

40. The microelectronic device of claim 38 wherein the substrate comprises a semiconductor material.

41. The microelectronic device of claim 38 wherein the substrate comprises silicon, gallium arsenide, silicon nitride, silicon oxide, silicon oxycarbide, silicon dioxide, silicon carbide, silicon oxynitride, titanium nitride, tantalum nitride, tungsten nitride, aluminum, copper, tantalum, organosiloxanes, organo silicon glass, fluorinated silicon glass or combinations thereof.

42. The microelectronic device of claim 38 wherein the nanoporous silica dielectric film is patterned to have formed at least one via and/or trench therein.

43. The microelectronic device of claim 38 wherein the patterned nanoporous silica dielectric film has an anti-reflective coating material deposited into the at least one via and/or trench.
